(19) United States
(12) Patent Application Publication
(10) Pub. No.: US 2010/0059209 A1
(43) Pub. Date: Mar. 11, 2010

(54) HEAT DISSIPATING DEVICE

(76) Inventors: Alex HORNG, Kaohsiung (TW); Miyahara Masaharu, Kaohsiung (TW); Hu Heng-Yu, Kaohsiung (TW)

Correspondence Address: Muncy, Geissler, Olds & Lowe, PLLC, P.O. BOX 1364, FAIRFAX, VA, 22038-1364, US

(21) Appl. No.: 12/248,740

(22) Filed: Oct. 9, 2008

(30) Foreign Application Priority Data
Sep. 9, 2008 (TW) 097134608

(51) Int. Cl. H01L 23/467

(52) U.S. Cl. 165/121

(57) ABSTRACT

A heat dissipating device includes a fan, a heat sink, and a heat conductive member. The heat sink includes a base having opposite first and second faces. The first face includes a plurality of fins extending from a peripheral area thereof. The fins define a compartment in which the fan is mounted. The second face includes a central section corresponding to the compartment receiving the fan. The second face further includes a peripheral section corresponding to the peripheral area from which the fins extend. The heat conductive member is mounted to the second face of the base and adapted to be in contact with a heat-generating member. The heat conductive member includes at least one heat pipe extending from the central section to the peripheral section.

### BACKGROUND OF THE INVENTION

1. Field of the Invention

The present invention relates to a heat dissipating device and, more particularly, to a heat dissipating device coupled to a heat-generating member, so that the heat generated by the member can be effectively and rapidly conducted to the fins of the heat dissipating device for heat dissipating purposes.

2. Description of the Related Art

A typical conventional heat dissipating device includes a heat sink having a base. The base includes two parallel faces one of which is in contact with a heat-generating member. A plurality of fins extends from a peripheral area of the other face of the base and defines a compartment between the fins. A fan is mounted in the compartment. The heat generated by the heat-generating member is conducted to the base and then to the fins. The fan rotates to create circulating air currents to assist in heat dissipation of the fins.

However, the heat can not be rapidly transmitted from a center of the base to the peripheral area due to limitation of the coefficient of heat conduction of the heat sink. As a result, the heat can not be rapidly conducted to the fins, leading to high heat. The situation worsens when the heat is concentrated in the center of the base.

### SUMMARY OF THE INVENTION

The primary objective of the present invention is to provide a heat dissipating device that can rapidly conduct heat generated by a heat-generating member to the fins of the heat dissipating device.

A heat dissipating device according to the preferred teachings of the present invention includes a fan, a heat sink, and a heat conductive member. The heat sink includes a base having opposite first and second faces. The first face includes a plurality of fins extending from a peripheral area thereof. The fins define a compartment in which the fan is mounted. The second face includes a central section corresponding to the compartment receiving the fan. The second face further includes a peripheral section corresponding to the peripheral area from which the fins extend. The heat conductive member is mounted to the second face of the base and adapted to be in contact with a heat-generating member. The heat conductive member includes at least one heat pipe extending from the central section to the peripheral section.

The heat conductive member has a coefficient of heat conduction larger than that of the heat sink, so that the heat generated by the heat-generating member can be rapidly transmitted to the peripheral section of the base. Thus, heat transmitted to the base can be rapidly transmitted to the fins.

The present invention will become clearer in light of the following detailed description of illustrative embodiments of this invention described in connection with the drawings.

### BRIEF DESCRIPTION OF THE DRAWINGS

The illustrative embodiments may best be described by reference to the accompanying drawings where:

FIG. 1 shows an exploded, perspective view of a heat dissipating device a first embodiment according to the preferred teachings of the present invention.

FIG. 2 shows a bottom view of the heat dissipating device of FIG. 1.

FIG. 3 shows a cross sectional view of the heat dissipating device of FIG. 1 according to section line 3-3 of FIG. 2.

FIG. 4 shoes an exploded, perspective view of a heat dissipating device of a second embodiment according to the preferred teachings of the present invention.

FIG. 5 shows a bottom view of the heat dissipating device of FIG. 4.

FIG. 6 shows a cross sectional view of the heat dissipating device of FIG. 4 according to section line 6-6 of FIG. 5.

All figures are drawn for ease of explanation of the basic teachings of the present invention only; the extensions of the figures with respect to number, position, relationship, and dimensions of the parts to form the preferred embodiments will be explained or will be within the skill of the art after the following teachings of the present invention have been read and understood. Further, the exact dimensions and dimensional proportions to conform to specific force, weight, strength, and similar requirements will likewise be within the skill of the art after the following teachings of the present invention have been read and understood.

Where used in the various figures of the drawings, the same numerals designate the same or similar parts. Furthermore, when the terms “first”, “second”, “end”, “portion”, “section”, “central”, “peripheral”, and similar terms are used herein, it should be understood that these terms have reference only to the structure shown in the drawings as it would appear to a person viewing the drawings and are utilized only to facilitate describing the invention.

### DETAILED DESCRIPTION OF THE INVENTION

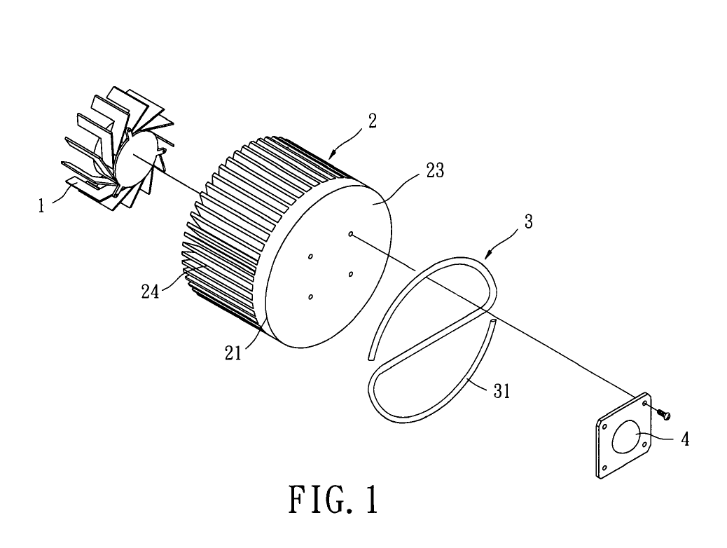

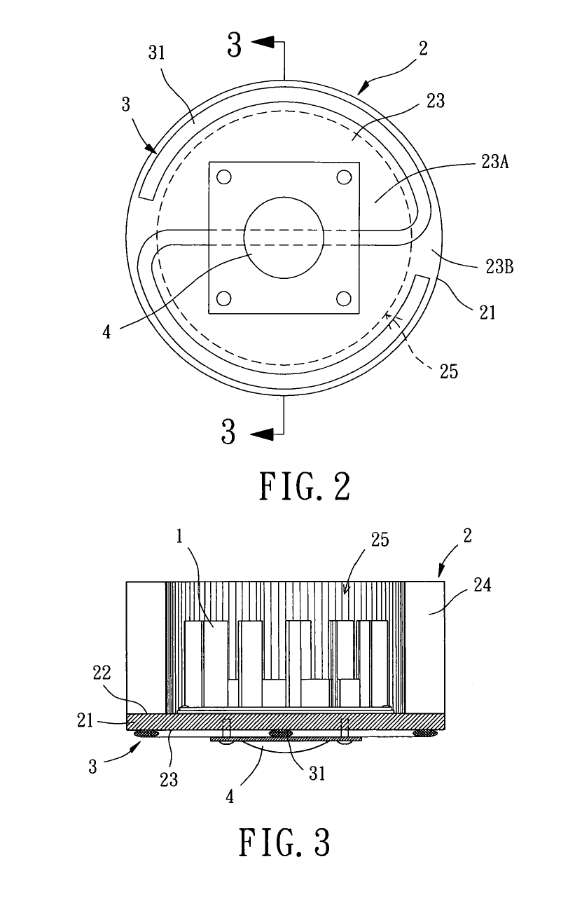

A heat dissipating device of a first embodiment according to the preferred teachings of the present invention is shown in FIGS. 1 to 3 of the drawings. According to the preferred form shown, the heat dissipating device includes a fan 1, a heat sink 2, and a heat conductive member 3. The heat sink 2 includes a base 21 having opposite first and second faces 22 and 23 that are preferably parallel to each other. The first face 22 includes a plurality of fins 24 extending from a peripheral area thereof The fins 24 define a compartment 25 therebetween for receiving the fan 1. The second face 23 includes a central section 23A corresponding to the compartment 25. The second face 23 further includes a peripheral section 23B corresponding to the peripheral area from which the fins 24 extend.

According to the preferred form shown, the heat conductive member 3 is a heat pipe 31 bent to be in the form of an S-shaped structure. It can be appreciated that the heat conductive member 3 can include two heat pipes 31 that are bent and then coupled together to form an S-shaped structure. According to the most preferred form shown, the heat pipe 31 includes a central portion and two arms each having an end interconnected to the central portion. The arms extend toward each other with a gap defined between two distal ends of the arms.

In assembly, the fan 1 is mounted in the compartment 25 of the heat sink 2. The heat conductive member 3 is mounted to the second face 23 of the base 21 of the heat sink 2 and in contact with a heat-generating member 4 such as a light-emitting diode (LED). The heat-generating member 4 is fixed to the second face 23 of the base 21 by screwing, insertion, bonding, or other provisions, so that the heat-generating member 4, the heat conductive member 3, and the second face 23 are in intimate contact with each other. Furthermore, the central portion of the heat pipe 31 is in contact with the central section 23A of the second face 23 of the base 21, and each arm of the heat pipe 31 extends along the peripheral section 23B of the second face 23 of the base 21. The arms of the heat pipe 31 cover most portion of the peripheral section 23B or even the whole peripheral section 23B. By such an arrangement, the heat generated by the heat-generating member 4 can be rapidly transmitted to the peripheral section 23B of the second face 23 through the heat conductive member 3. Thus, the heat transmitted to the base 21 can be rapidly transmitted to the fins 24.

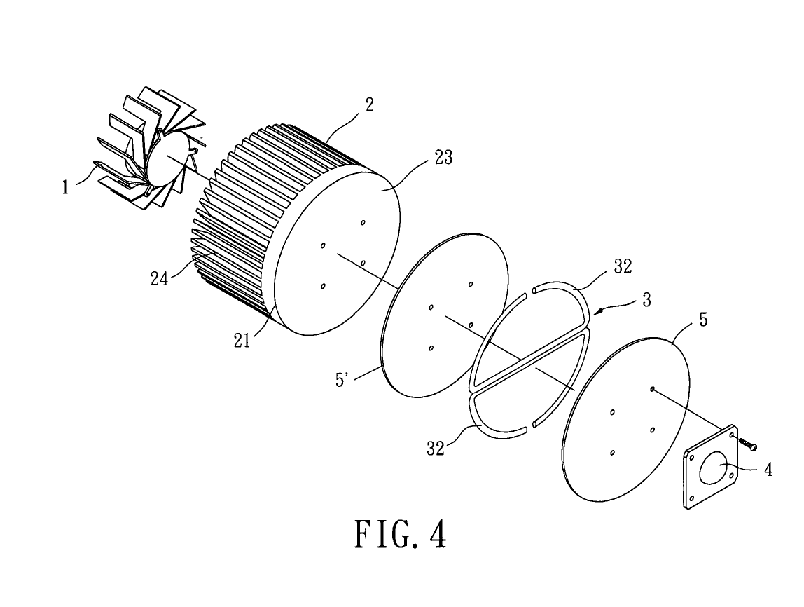

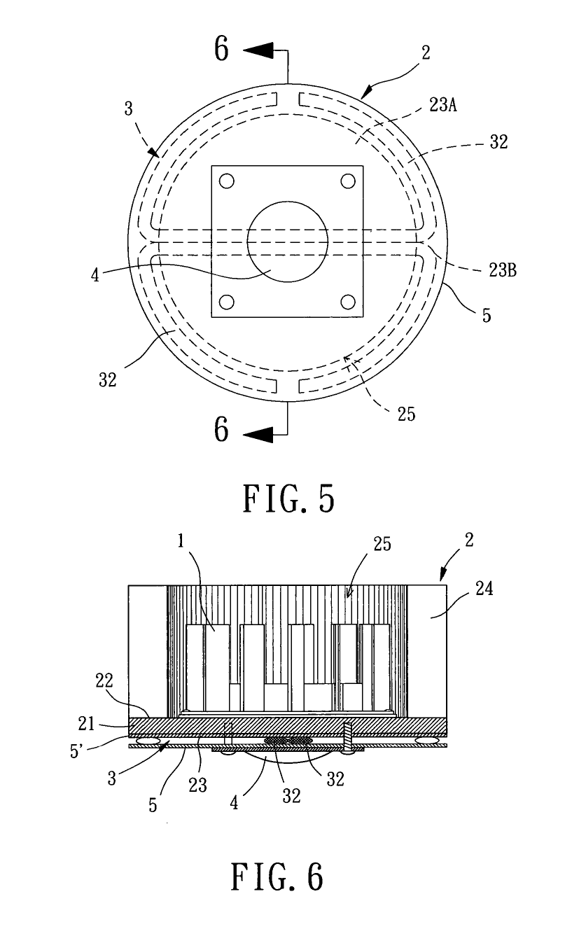

A heat dissipating device of a second embodiment according to the preferred teachings of the present invention is shown in FIGS. 4 to 6. According to the preferred form shown, the heat dissipating device includes a fan 1, a heat sink 2, a heat conductive member 3, and two plates 5 and 5′. The fan 1 and the heat sink 2 are identical to the fan 1 and the heat sink 2 of the first embodiment. The heat conductive member 3 of the second embodiment includes two substantially C-shaped heat pipes 32 each having a central portion and two arms each of which has an end interconnected to the central portion. The arms extend toward each other with a gap defined between two distal ends of the arms. The central portions of the heat pipes 32 are coupled together by welding, bonding or other provisions. The plates 5 and 5′ are made of heat conductive materials. Preferable materials for plates 5 and 5′ include but not limited to copper. The plates 5 and 5′ have cross sections the same as that of the base 21.

In assembly, the fan 1 is mounted in compartment 25 of heat sink 2. The heat conductive member 3 is sandwiched between the plates 5 and 5′. Furthermore, one of the plates 5′ is mounted to the second face 23 of the base 2. Further, the coupling area of the two heat pipes 32 is in contact with the central section 23A of the second face 23. Each arm of each heat pipe 32 extends along the peripheral section 23B. The other plate 5 is in contact with the heat-generating member 4 that is preferably fixed by extending screws through the plates 5 and 5′ into the second face 23 of the heat sink 2. Thus, the heat-generating member 4, the plates 5 and 5′, the heat conductive member 3, and the second face 23 are in intimate contact with each other. Although there are two plates 5 and 5′ in the preferred form shown, one of them can be omitted if desired.

The heat conductive member 3 has a coefficient of heat conduction larger than that of the heat sink 2, so that the heat generated by the heat-generating member 4 can be rapidly transmitted to the peripheral section 23B of the base 21. Thus, heat transmitted to the base 21 can be rapidly transmitted to the fins 24.

Thus since the invention disclosed herein may be embodied in other specific forms without departing from the spirit or general characteristics thereof, some of which forms have been indicated, the embodiments described herein are to be considered in all respects illustrative and not restrictive. The scope of the invention is to be indicated by the appended claims, rather than by the foregoing description, and all changes which come within the meaning and range of equivalency of the claims are intended to be embraced therein.

What is claimed is:

1. A heat dissipating device comprising, in combination:
a fan;
a heat sink including a base having opposite first and second faces, with the first face including a plurality of fins extending from a peripheral area thereof, with the fins defining a compartment therebetween, with the fan mounted in the compartment, with the second face including a central section corresponding to the compartment receiving the fan, with the second face further including a peripheral section corresponding to the peripheral area from which the plurality of fins extends; and
a heat conductive member mounted to the second face of the base and adapted to be in contact with a heat-generating member, with the heat conductive member extending from the central section to the peripheral section.

2. The heat dissipating device as claimed in claim 1, with the heat conductive member including at least one heat pipe extending on the second face of the base.

3. The heat dissipating device as claimed in claim 2, with said at least one heat pipe being S-shaped and including a central portion in contact with the heat-generating member.

4. The heat dissipating device as claimed in claim 3, with said at least one heat pipe further including two arms each having an end interconnected to the central portion, and with each of the two arms extending along the peripheral section of the second face of the base.

5. The heat dissipating device as claimed in claim 1, with the heat conductive member including two substantially C-shaped heat pipes each having a central portion in contact with the heat-generating member.

6. The heat dissipating device as claimed in claim 5, with each of the two heat pipes further including two arms each having an end interconnected to the central portion, and with each of the two arms of each of the two heat pipes extending along the peripheral section of the second face of the base.

7. The heat dissipating device as claimed in claim 1, further comprising, in combination: a first plate mounted between the heat conductive member and the heat-generating member.

8. The heat dissipating device as claimed in claim 7, further comprising, in combination: a second plate mounted between the heat conductive member and the heat sink.

9. The heat dissipating device as claimed in claim 1, further comprising, in combination: a plate mounted between the heat conductive member and the heat sink.
